(19) United States
(12) Patent Application Publication
(10) Pub. No.: US 2022/0302382 A1
(43) Pub. Date: Sep. 22, 2022

(54) SEMICONDUCTOR STORAGE DEVICE

(71) Applicant: Kioxia Corporation, Tokyo (JP)

(72) Inventor: Ken HOSHINO, Yokkaichi Mie (JP)

(73) Assignee: Kioxia Corporation, Tokyo (JP)

(21) Appl. No.: 17/462,302

(22) Filed: Aug. 31, 2021

(30) Foreign Application Priority Data
Mar. 16, 2021 (JP) 2021-042876

(51) Int. Cl. H01L 45/00; H01L 27/24

(52) U.S. Cl. CPC H01L 45/126; H01L 27/2427; H01L 45/06; H01L 45/1675

(57) ABSTRACT

A semiconductor storage device includes at least a first electrode layer including a first material; and a memory layer including a second material having a high-resistance state and a low-resistance state switchable based on electric heating. The memory layer has a side surface covered by a side wall layer, the side wall layer including a third material with a higher melting temperature than the second material. The first material has an amorphous structure, a thermal conductivity at least 2-digits lower than a thermal conductivity of a single phase metal, and a resistivity equal to or lower than 50 mΩ·cm and a positive temperature dependence.

### CROSS-REFERENCE TO RELATED APPLICATION(S)

This application is based upon and claims the benefit of priority from Japanese Patent Application No. 2021-042876, filed Mar. 16, 2021, the entire contents of which are incorporated herein by reference.

### FIELD

Embodiments described herein relate generally to a semiconductor storage device.

### BACKGROUND

Variable-resistance semiconductor storage devices that store information by varying resistance values of memory cells are known as large-capacity semiconductor storage devices.

### DESCRIPTION OF THE DRAWINGS

FIG. 1 is a block diagram of a semiconductor storage device according to a first embodiment.

FIG. 2 is a circuit diagram showing a structure of a memory cell array of the semiconductor storage device.

FIG. 3 is a perspective view showing a structure of the memory cell array.

FIG. 4 is a partial sectional view showing a main part of a memory mat provided in the memory cell array.

FIG. 5 is a partial sectional view showing a main part of a memory mat of a second embodiment provided in the memory cell array.

FIG. 6 is a partial sectional view showing a main part of a memory mat of a third embodiment provided in the memory cell array.

FIG. 7 is a partial sectional view showing a main part of a memory mat of a fourth embodiment provided in the memory cell array.

FIG. 8 is a partial sectional view showing a main part of a memory mat of a fifth embodiment provided in the memory cell array.

FIG. 9 is a partial sectional view showing a main part of a memory mat of a sixth embodiment provided in the memory cell array.

FIG. 10 is a partial sectional view showing a method for manufacturing a memory mat of the semiconductor storage device in one embodiment.

FIG. 11 is a partial sectional view showing the method for manufacturing the memory mat of the semiconductor storage device in the one embodiment.

FIG. 12 is a partial sectional view showing the method for manufacturing the memory mat of the semiconductor storage device in the one embodiment.

FIG. 13 is a partial sectional view showing the method for manufacturing the memory mat of the semiconductor storage device in the one embodiment.

FIG. 14 is a partial sectional view showing the method for manufacturing the memory mat of the semiconductor storage device in the one embodiment.

FIG. 15 is a partial sectional view showing the method for manufacturing the memory mat of the semiconductor storage device in the one embodiment.

FIG. 16 is a partial sectional view showing the method for manufacturing the memory mat of the semiconductor storage device in the one embodiment.

FIG. 17 is a graph showing temperature dependence of thermal conductivity with respect to carbon and amorphous alloy that are used in a phase change film of a memory mat.

FIG. 18 is a graph showing result of X-ray diffraction analysis of the amorphous alloy at each temperature.

FIG. 19 is a partial sectional view showing effects of replacing carbon films that constitute electrodes with amorphous alloy films in one embodiment of a memory mat of the semiconductor device.

### DETAILED DESCRIPTION

This type of semiconductor storage device employs a structure configured to write and erase information in accordance with change in the state of a storage layer that records information. The change is induced by electrically heating an electrode layer connected to the storage layer. In view of this, in order to promote integration in a semiconductor storage device, electrode layers should be thinned. Moreover, a current value at the time of resetting the state of a storage layer in order to erase information stored therein is desirably as low as possible.

Embodiments provide a semiconductor storage device that enables reduction in film thickness of an electrode layer and decrease in reset current.

In general, according to one embodiment, a semiconductor storage device includes at least a first electrode layer including a first material; and a memory layer including a second material having a high-resistance state and a low-resistance state switchable based on electric heating. The memory layer has a side surface covered by a side wall layer, the side wall layer including a third material with a higher melting temperature than the second material. The first material has an amorphous structure, a thermal conductivity at least 2-digits lower than a thermal conductivity of a single phase metal, and a resistivity equal to or lower than 50 mΩ·cm and a positive temperature dependence.

### First Embodiment

Hereinafter, a semiconductor storage device of a first embodiment will be described with reference to the drawings.

In the following description, elements that have the same or similar function are denoted by the same reference signs. Duplicated descriptions of these elements may be omitted. In this specification, the term “connect” represents not only physical connection, but also electrical connection. In this specification, the term “adjacent” represents not only a state of two target elements being mutually adjacent, but also a state of two target elements being adjacent to each other across another element. In this specification, the phrase “xx is provided above yy” represents not only a state of the xx in contact with the yy, but also a state of the xx having another member between the xx and the yy. In this specification, the terms “parallel” and “orthogonal” include the meanings of “approximately parallel” and “approximately orthogonal”, respectively.

In addition, first, an X direction, a Y direction, and a Z direction are defined. The X direction and the Y direction are directions along a surface of a semiconductor substrate SB (described later). The X direction is an extending direction of a word line WL (described later). The Y direction crosses, for example, is orthogonal to, the X direction. The Y direction is an extending direction of a bit line BL (described later). The Z direction (first direction) crosses, for example, is orthogonal to, the X direction and the Y direction, which is a thickness direction of the semiconductor substrate SB. In this specification, a “+Z direction” may be referred to as “upper”, and a “−Z direction” may be referred to as “lower”. The +Z direction and the −Z direction differ from each other by 180 degrees. It is noted that these expressions are used for convenience only and do not specify the direction of gravity. The X direction and the Y direction may be collectively described as an “XY direction (second direction)”.

<1. Overall Configuration of Semiconductor Storage Device>

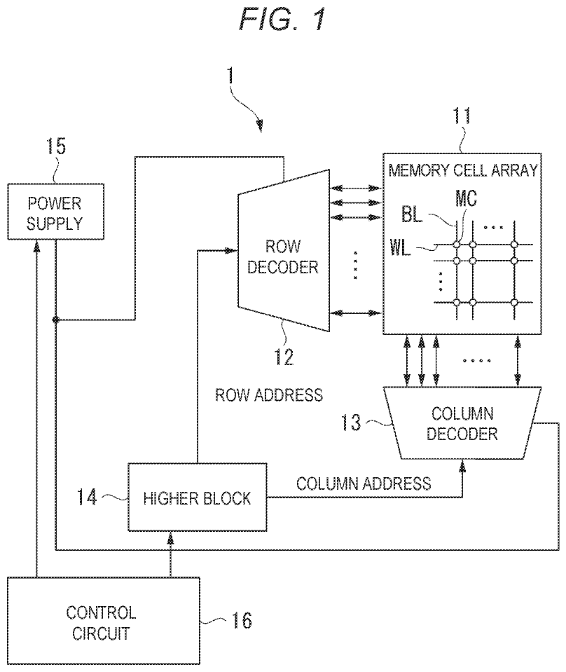

FIG. 1 is a block diagram showing an overall configuration of a semiconductor storage device according to a first embodiment.

A semiconductor storage device 1 according to the first embodiment includes a memory cell array 11, and a row decoder 12 and a column decoder 13 that select a desired memory cell MC from the memory cell array 11. The semiconductor storage device 1 also includes a higher block decoder 14, a power supply 15, and a control circuit 16. The higher block decoder 14 provides a row address and a column address to the corresponding decoders 12 and 13. The power supply 15 supplies power to each element of the semiconductor storage device 1. The control circuit 16 controls the higher block decoder 14 and the power supply 15.

The memory cell array 11 includes multiple memory cells MC that each store data of 1 bit or multiple bits. The memory cell array 11 is configured to enable access to a desired memory cell MC for erasing/writing/reading of data, in response to application of a predetermined voltage to a desired bit line BL and a desired word line WL selected by the row decoder 12 and the column decoder 13.

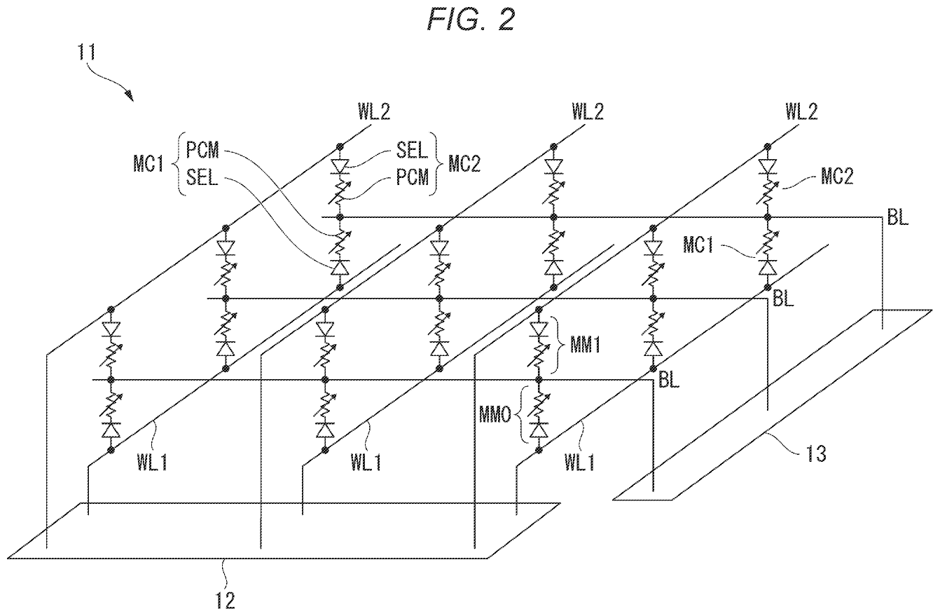

FIG. 2 is an equivalent circuit diagram showing a partial structure of the memory cell array 11.

The memory cell array 11 includes multiple bit lines BL, multiple word lines WL1 and WL2, and multiple memory cells MC1 and MC2 that are connected to the bit lines BL and the word lines WL1 and WL2.

The memory cells MC1 and MC2 are connected to the row decoder 12 via the word lines WL1 and WL2 and are also connected to the column decoder 13 via the bit lines BL. The memory cells MC1 and MC2 each store data of 1 bit, for example. Multiple memory cells MC1 and MC2 that are connected to the same word lines WL1 and WL2 store data of 1 page, for example.

Each of the memory cells MC1 and MC2 is composed of a series circuit of a phase change film PCM and a selector SEL.

The phase change film PCM is capable of having two states of a low-resistance crystalline state and a high-resistance amorphous state, depending on a current pattern or heating pattern. Thus, the phase change film PCM functions as a phase change film. The two kinds of states having different resistance values are corresponded to information of “0” and “1”, whereby the phase change film PCM functions as a memory cell. That is, the phase change film PCM functions as a storage layer. In the case of providing a selector SEL to each of the memory cells MC1 and MC2, each selector SEL functions as a rectifier. As a result, current hardly flows into word lines WL1 and WL2 other than selected word lines WL1 and WL2.

It is noted that, hereinafter, a structure including multiple bit lines BL, multiple word lines WL1, and multiple memory cells MC1, corresponding to a first layer of the memory cell array 11, can be called a “memory mat MM0”. Similarly, a structure including multiple bit lines BL, multiple word lines WL2, and multiple memory cells MC2, corresponding to a second layer of the memory cell array 11, can be called a “memory mat MM1”.

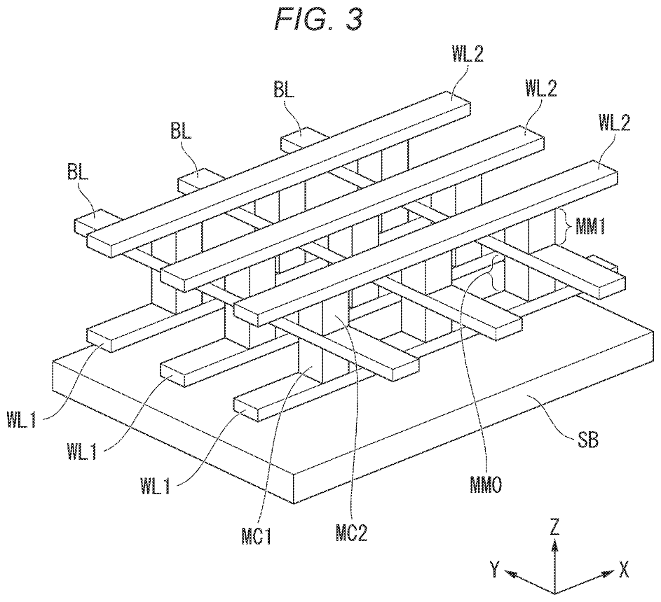

FIG. 3 is a schematic perspective view showing a partial structure of the memory cell array 11.

In this example, the memory cell array 11 is a cross-point memory cell array. That is, multiple word lines WL1 are arranged above the semiconductor substrate SB, with a predetermined interval in the Y direction parallel to an upper surface of the semiconductor substrate SB. The word lines WL1 are provided in such a manner as to extend parallel to the X direction, which is parallel to the upper surface of the semiconductor substrate SB and crosses the Y direction. In addition, multiple bit lines BL are arranged with a predetermined interval in the X direction, above the multiple word lines WL1, and are provided in such a manner as to extend parallel to the Y direction.

Moreover, multiple word lines WL2 are arranged with a predetermined interval in the Y direction, above the multiple bit lines BL, and are provided in such a manner as to extend parallel to the X direction. A memory cell MC1 is provided in each of parts where the multiple word lines WL1 and the multiple bit lines BL cross each other. Similarly, a memory cell MC2 is provided in each of parts where the multiple bit lines BL and the multiple word lines WL2 cross each other. It is noted that, although FIG. 3 shows an example of memory cells MC1 and MC2 having rectangular column shapes, the memory cells MC1 and MC2 may have circular column shapes or other shapes, and the shapes thereof are not limited.

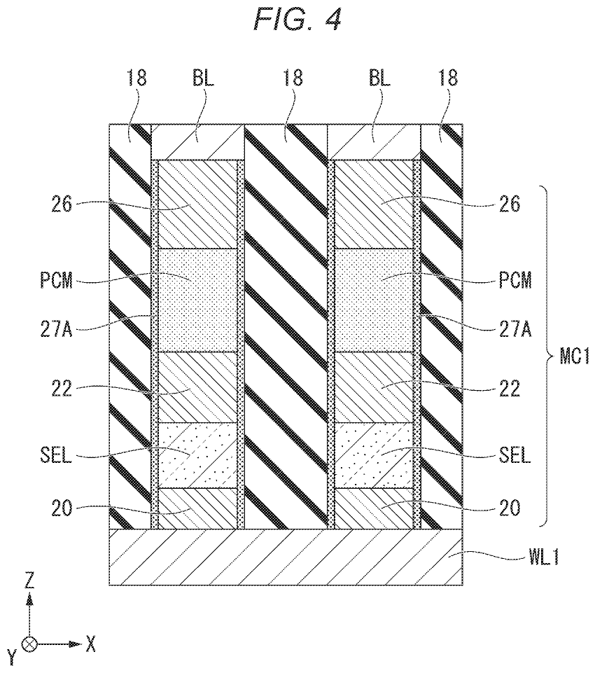

FIG. 4 is a sectional view showing a partial structure of the memory mat MM0. FIG. 4 shows an example of a cross section orthogonal to the Y direction. FIG. 4 shows a cross section of two adjacent memory cells MC1 and surrounding parts.

The memory mat MM0 includes a word line WL1, which is disposed on the semiconductor substrate SB side so as to extend in the X direction, and includes a bit line BL, which is disposed on a side opposite to the semiconductor substrate SB relative to the word line WL1, so as to extend in the Y direction. The memory mat MM0 also includes multiple memory cells MC1 that are disposed between the word line WL1 and the bit line BL and includes an insulating layer 18 that is provided between side surfaces in the XY direction (second direction) of the memory cells MC1.

The memory cell MC1 includes a lower electrode layer 20, a selector SEL, an intermediate electrode layer 22, a phase change film (variable resistance film, storage layer) PCM, and an upper electrode layer 26, which are stacked, in this order, in the Z direction (first direction) from the word line WL1 to the bit line BL. Protective layers (side wall layers) 27A cover side surfaces (circumferential surfaces) in the XY direction (second direction) of the memory cell MC1, which includes the lower electrode layer 20, the selector SEL, the intermediate electrode layer 22, the phase change film PCM, and the upper electrode layer 26.

The word line WL1 and the bit line BL are composed of a conductive material, such as tungsten (W), titanium (Ti), or poly-Si. In the example in FIG. 4, the lower electrode layer 20 is stacked above the word line WL1.

The insulating layer 18 is composed of an insulating material, such as silicon oxide (SiO₂) or silicon nitride (Si₃N₄).

The selector SEL may be, for example, a switching element between two terminals. In the state where voltage applied to the two terminals is a threshold or lower, the switching element is in a “high-resistance” state, for example, in an electrically non-conductive state. In the state where voltage applied to the two terminals is a threshold or higher, the switching element is in a “low-resistance” state, for example, in an electrically conductive state. The switching element may have this function with respect to voltage of either polarity. The switching element contains at least one kind of chalcogen element selected from the group consisting of Te, Se, and S. The switching element may contain a chalcogenide that is a compound containing the chalcogen element described above. The switching element may also contain at least one kind of element selected from the group consisting of B, Al, Ga, In, C, Si, Ge, Sn, As, P, and Sb.

In the first embodiment, the lower electrode layer 20, the intermediate electrode layer 22, and the upper electrode layer 26 are formed of an amorphous alloy (first material) that shows an amorphous structure. The amorphous alloy preferably remains having the amorphous structure from normal temperature to approximately 900° C. The amorphous alloy has an amorphous structure in which a diffraction peak is difficult to observe when a diffraction chart is obtained by electron diffraction. For example, the amorphous alloy has a thermal conductivity 2-digits lower than that of a single phase metal and has a resistivity of 50 mΩ·cm or lower and a positive temperature dependence.

An example of the amorphous alloy (first material) includes an alloy containing two or more refractory metals M1. The refractory metal M1 is one or two or more kinds selected from the group consisting of W, Mo, Ta, Nb, Rh, and Ni.

Another example of the amorphous alloy includes an alloy containing two or more refractory metals M1 and also containing one or more semimetal or nonmetal elements M2. The element M2 is one or two or more kinds selected from the group consisting of B, C, N, Al, Si, P, S, Ge, As, and Se.

More specifically, for example, it is possible to use one or two or more kinds of amorphous alloys that are represented as composition formulas Ta₁W₁Si₁, Ta₄₀W₄₀Si₂₀, Ta₃₀W₅₀Si₂₀, and Ta₃₀W₃₀Si₄₀.

For example, in an amorphous alloy having a composition consisting of the refractory metal M1 and the element M2, an element M2 having an atomic radius at the time of covalent bonding smaller than that of the refractory metal M1 by 12% or more, may be selected.

An example of the amorphous alloy includes an alloy containing Fe and one or more elements M3. The element M3 is one or two or more kinds selected from the group consisting of Tb, Gd, Co, B, Ni, Cr, and P.

More specifically, for example, it is possible to use one or two or more kinds of amorphous alloys that are represented by composition formulas Tb₂₁Fe₇₃Co₆, Gd₂₁Fe₇₂Co₇, Fe₈₀B₂₀, and Fe₃₂Ni₃₆Cr₁₄P₁₂B₆.

An example of the amorphous alloy includes an alloy containing Zr, Cu, and one or more elements M4. The element M4 is one or two or more kinds selected from the group consisting of Al, Ni, Ti, Nb, and Be.

More specifically, for example, it is possible to use one or two or more kinds of amorphous alloys that are represented by composition formulas Zr₄₇Cu₃₁Al₁₃Ni₉, Zr_{56.2}Ti_{1.83}Nb_{5.5}Cu_{6.9}Ni_{5.6}Be_{12.5} (at %), Zr₅₅Cu₃₀Al₁₀Ni₅, and Zr₄₁Ti₁₄Cu₁₂Ni₁₀Be₂₃.

An example of the amorphous alloy includes an alloy containing Pd, Ni, and P or both of P and Cu.

More specifically, for example, it is possible to use one or two or more kinds of amorphous alloys that are represented by composition formulas Pd₄₀Ni₄₀P₂₀, Pd₄₀Ni₂₀Cu₂₀P₂₀, and Pd₄₀Ni₁₀Cu₃₀P₂₀.

The above-described amorphous alloy, which does not have a lattice pattern, has low phonon conduction, low thermal conductivity or high heat insulation characteristic, and no crystal structure. Thus, a thin film that is made of this amorphous alloy has a smooth surface layer in an atomic level. In one example, an amorphous alloy film having a composition of Ta₁W₁Si₁ and having a film thickness of 200 nm exhibits RMS (surface roughness)=0.18 nm, whereas a carbon film having a film thickness of 1.3 μm exhibits RMS=9.43 to 10.36 nm, and a Ta film having a film thickness of 500 nm exhibits RMS=2.1 nm. In view of this, an electrode layer that is formed of the above-described amorphous alloy can have a surface smoother than those of a metal film and a carbon film. Thus, contact characteristics between an electrode layer and other conductive layer can be improved.

It is known that a surface roughness of an amorphous alloy film having a composition of Ta₄₀W₄₀Si₂₀ is 0.3 nm, a surface roughness of an amorphous alloy film having a composition of Ta₃₀W₅₀Si₂₀ is 0.5 nm, and a surface roughness of an amorphous alloy film having a composition of Ta₃₀W₃₀Si₄₀ is 0.25 nm. This shows that an amorphous alloy film having any TaWSi system composition tends to have a smooth surface.

When an electrode layer has a large surface roughness, the electrode layer includes multiple minute protrusions at an interface in contact with other conductive layer or other thin film. Thus, an electric field may concentrate on the protrusions being electrically connecting parts, which changes operation of the electrode layer as a device, resulting in reduction in reliability. On the other hand, an amorphous alloy electrode layer has a smooth electrical contact surface, as described above, and has a reduced effective surface area, whereby the amorphous alloy electrode layer contributes to reduction in reset current I_{RESET}.

The phase change film (variable resistance film, storage layer) PCM contains a chalcogen. Chalcogens are elements belonging to the group 16 in the periodic table. The phase change film PCM contains, for example, sulfur (S), selenium (Se), or tellurium (Te), among the chalcogens excluding oxygen (O). The phase change film PCM may be a chalcogenide film. Chalcogenides are compounds containing chalcogen and are, for example, GeSbTe, GeTe, SbTe, and SiTe. That is, the phase change film PCM may be one containing at least one kind of element selected from the group consisting of germanium, antimony, and tellurium.

The protective layer (side wall layer) 27A is composed of, for example, a material equivalent to that of the phase change film PCM and at least one kind of element selected from the group consisting of nitrogen (N), carbon (C), boron (B), and oxygen (O). The protective layer 27A may be formed of a layer containing an element that composes the phase change film PCM, for example, at least one kind of element selected from the group consisting of germanium (Ge), antimony (Sb), and tellurium (Te), and containing at least one kind of element selected from the group consisting of nitrogen (N), carbon (C), boron (B), and oxygen (O).

Elements such as nitrogen (N), carbon (C), boron (B), and oxygen (O), increase the melting temperature of the protective layer 27A. Thus, in the first embodiment, for example, the melting temperature of the protective layer 27A is higher than that of the phase change film PCM. More specifically, the melting temperature of the protective layer 27A is higher than heat that is applied to the phase change film PCM at the time of access to the memory cell MC1. In one example, the melting temperature of the protective layer 27A is higher than 500° C. As a result, the protective layer 27A is not melted by access to the memory cell MC, but remains in the solid state. In these conditions, the protective layer 27A has a high-resistance amorphous state. Thus, the crystallization temperature of the protective layer 27A is higher than the melting temperature of the phase change film PCM.

The phase change film PCM becomes an amorphous state (reset state) when being heated to the melting temperature or higher and then being rapidly cooled. On the other hand, the phase change film PCM becomes a crystalline state (set state) when being heated at a temperature lower than the melting temperature but higher than the crystallization temperature and then being gradually cooled. Thus, the phase change film PCM repeats melting and solidification by resetting and setting.

From this point of view, the phase change film PCM can be described as being composed of a memory substance that is made of a second material in which the resistivity in the high-resistance state and the resistivity in the low-resistance state are switchable by electric heating.

If the protective layer 27 is not provided, repetition of melting and solidification of the phase change film PCM may form a void at an interface between the phase change film PCM and the insulating layer 18, may cause segregation of composition elements, or may cause reaction and diffusion of composition elements with respect to a surrounding material. These phenomena can bring about deterioration of the phase change memory.

In the state where the protective layer 27A is formed at an interface between the phase change film PCM and the insulating layer 18, as in the structure of this embodiment, the protective layer 27A, which contains a composition element of the phase change film PCM, has a good affinity with the phase change film PCM, and they stably combine with each other. The protective layer 27A has an increased melting temperature due to addition of an element such as N, C, B, or O, and thereby remains in the solidified amorphous state. This suppresses phenomena such as void formation, segregation, composition change, and reaction and diffusion, between the phase change film PCM and the insulating layer 18.

In addition, the protective layer 27A remains in the amorphous state and thus has a high resistance value, whereby current hardly flows thereinto. That is, the protective layer 27A does not affect the value of current that flows between the lower electrode layer 20 and the upper electrode layer 26.

FIG. 5 shows a memory cell MC12 of a second embodiment. The memory cell MC12 includes a lower electrode layer 20, a selector SEL, an intermediate electrode layer 22, a barrier layer 23, a phase change film (storage layer) PCM, a barrier layer 25, and an upper electrode layer 26, which are stacked, in this order, in the Z direction from the word line WL1 to the bit line BL.

Protective layers (side wall layers) 27B cover side surfaces (circumferential surfaces) in the XY direction (second direction) of the memory cell MC12, which includes the lower electrode layer 20, the selector SEL, the intermediate electrode layer 22, the barrier layer 23, the phase change film PCM, the barrier layer 25, and the upper electrode layer 26. In the structure in FIG. 5, the lower electrode layer 20 is stacked above the word line WL1.

The memory cell MC12 of the second embodiment shown in FIG. 5 has a structure in which the barrier layers 23 and 25 are added in the structure of the memory cell MC1 of the first embodiment shown in FIG. 4. The barrier layer 23 is provided in such a case that direct stacking of the intermediate electrode layer 22 and the phase change film PCM is undesirable due to occurrence of diffusion of elements or the like. Also, the barrier layer 25 is provided in such a case that direct stacking of the phase change film PCM and the upper electrode layer 26 is undesirable due to occurrence of diffusion of elements or the like. Conversely, when the combinations of the materials of the electrodes 22 and 26 made of the above-described amorphous alloy, and the phase change film PCM, cause no problem in direct stacking thereof, the barrier layers 23 and 25 may be omitted as in the memory cell MC1 shown in FIG. 4.

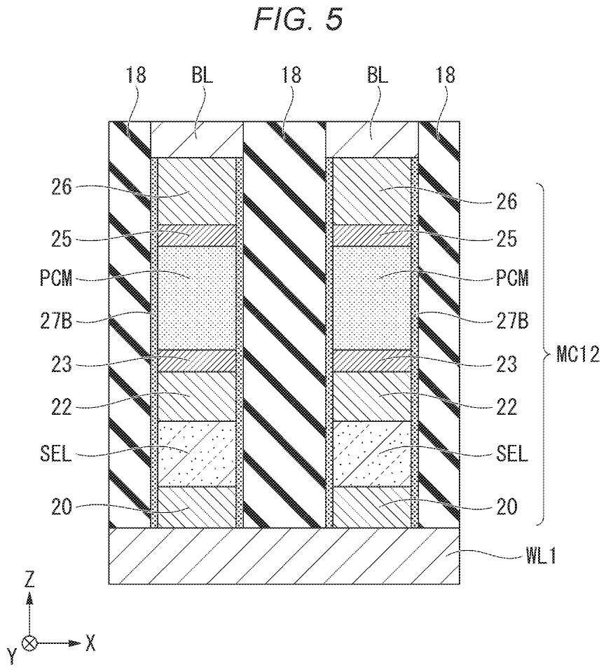

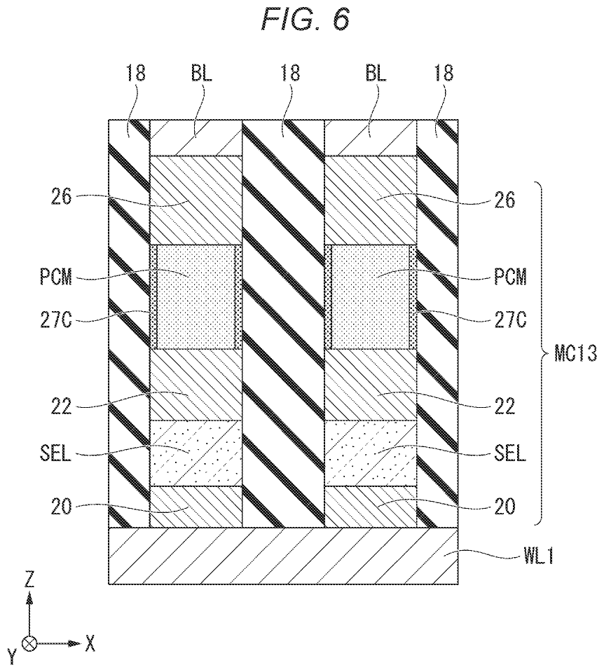

FIG. 6 shows a memory cell MC13 of a third embodiment. The memory cell MC13 includes a lower electrode layer 20, a selector SEL, an intermediate electrode layer 22, a phase change film (variable resistance film, storage layer) PCM, and an upper electrode layer 26, which are stacked, in this order, in the Z direction (first direction) from the word line WL1 to the bit line BL. Protective layers (side wall layers) 27C cover side surfaces (circumferential surfaces) in the XY direction (second direction) of the phase change film PCM.

The protective layer 27C may cover the side surfaces (circumferential surfaces) of only the phase change film PCM, as shown in FIG. 6.

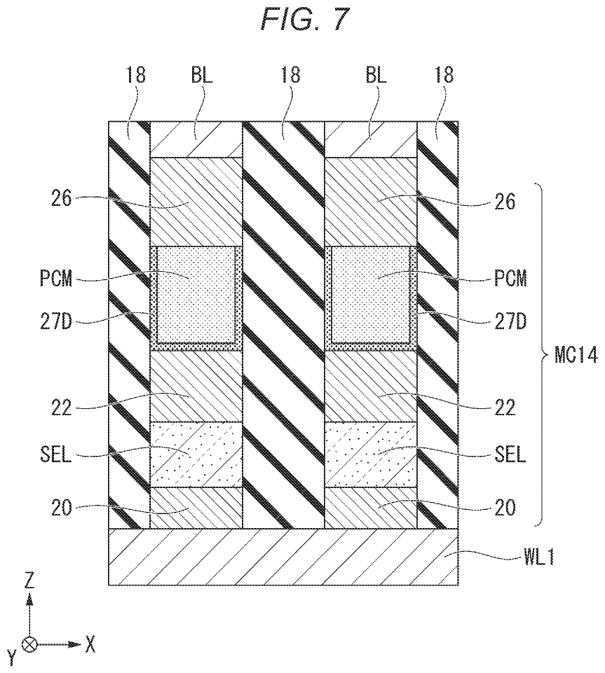

FIG. 7 shows a memory cell MC14 of a fourth embodiment. The memory cell MC14 includes a lower electrode layer 20, a selector SEL, an intermediate electrode layer 22, a phase change film (variable resistance film, storage layer) PCM, and an upper electrode layer 26, which are stacked, in this order, in the Z direction (first direction) from the word line WL1 to the bit line BL. Protective layers (side wall layers) 27D cover side surfaces (circumferential surfaces) in the XY direction (second direction) and a bottom surface in the −Z direction, of the phase change film PCM.

The protective layer 27D may cover the side surfaces and the bottom surface of the phase change film PCM, as shown in FIG. 7.

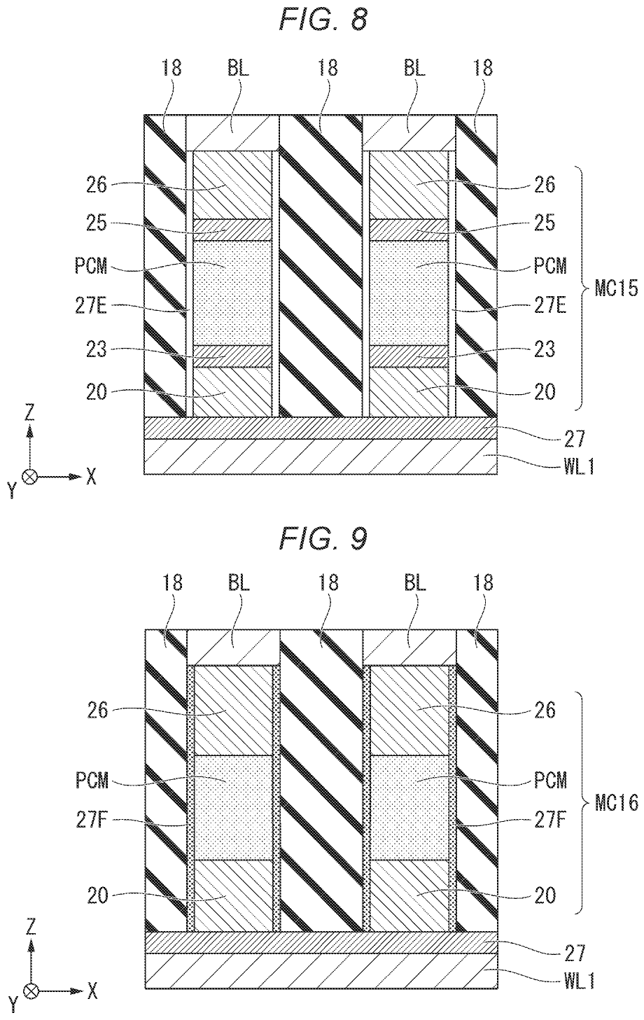

FIG. 8 shows a memory cell MC15 of a fifth embodiment. The memory cell MC15 includes a lower electrode layer 20, a barrier layer 23, a phase change film (variable resistance film, storage layer) PCM, a barrier layer 25, and an upper electrode layer 26, which are stacked, in this order, in the Z direction (first direction) from the word line WL1 to the bit line BL.

Protective layers (side wall layers) 27E cover side surfaces (circumferential surfaces) in the XY direction (second direction) of the memory cell MC15, which includes the lower electrode layer 20, the barrier layer 23, the phase change film PCM, the barrier layer 25, and the upper electrode layer 26. In the structure in FIG. 8, the lower electrode layer 20 is stacked via a barrier layer 27 that is formed above the word line WL1.

A structure excluding a selector, as in this embodiment, may also be employed.

FIG. 9 shows a memory cell MC16 of a sixth embodiment. The memory cell MC16 includes a lower electrode layer 20, a phase change film (variable resistance film, storage layer) PCM, and an upper electrode layer 26, which are stacked, in this order, in the Z direction (first direction) from the word line WL1 to the bit line BL. Protective layers (side wall layers) 27F cover side surfaces (circumferential surfaces) in the XY direction (second direction) of the lower electrode layer 20, the phase change film PCM, and the upper electrode layer 26.

A structure excluding the barrier layers 23 and 25, as in this embodiment, may also be employed.

Basically, the barrier layers 23 and 25 are provided in order to prevent a phenomenon such as mutual element diffusion between the electrode layers 20 and 26 and the phase change film PCM. However, when the lower electrode layer 20 and the upper electrode layer 26 that are made of the above-described amorphous alloy are directly stacked on the phase change film PCM, mutual element diffusion therebetween does not occur, whereby the barrier layers can be omitted.

Next, a method for manufacturing memory cells of the foregoing embodiment will be described.

As shown in FIG. 10, a conductive layer 200 for the word line WL, a conductive layer 211 for the lower electrode layer 20, a semiconductor layer 221 for the selector SEL, a conductive layer 231 for the intermediate electrode layer 22, a phase change film 241 for the phase change film PCM, and a conductive layer 251 for the upper electrode layer 26, are sequentially formed above a semiconductor substrate (not shown) by a film deposition method, such as atomic layer deposition (ALD) or chemical vapor deposition (CVD). Thereafter, a hard mask 301 is formed above the conductive layer 251 by lithography.

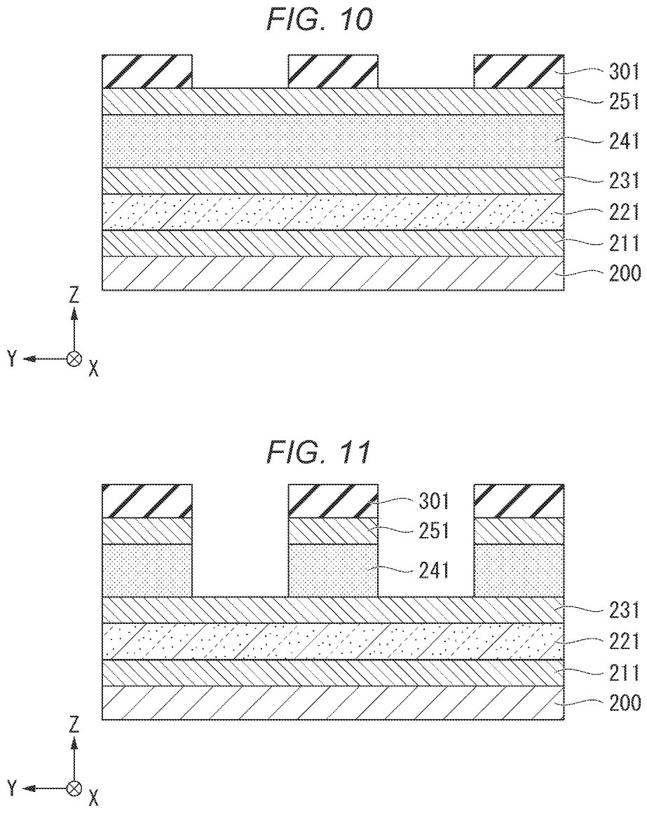

Next, as shown in FIG. 11, the stacked structure body from the conductive layer 251 to the phase change film PCM1 is divided in the Y direction by anisotropic etching, such as reactive ion etching (RIE), using the hard mask 301.

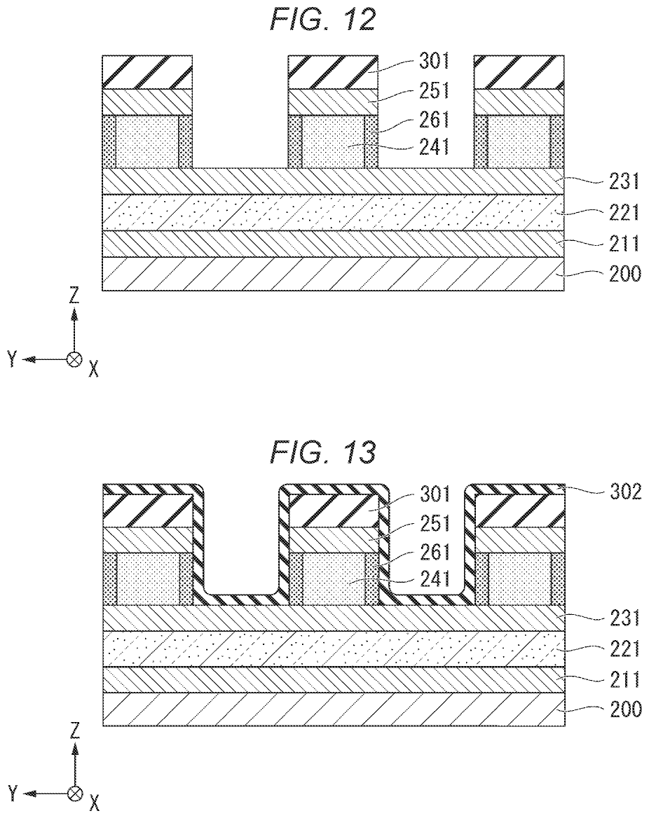

Then, as shown in FIG. 12, at least one kind of element selected from the group consisting of N, C, B, and O is implanted in side surfaces in the Y direction of the phase change film PCM1 by a method such as ion implantation, plasma doping, or annealing treatment after gas implantation, whereby protective layers 261 are formed.

Subsequently, as shown in FIG. 13, the upper surface of the stacked structure body is covered with an insulating film 302 in such a manner that side surfaces of the phase change film PCM1 are covered. The insulating film 302 is configured to protect the side surfaces of the phase change film PCM1 from damage in anisotropic etching that is performed later.

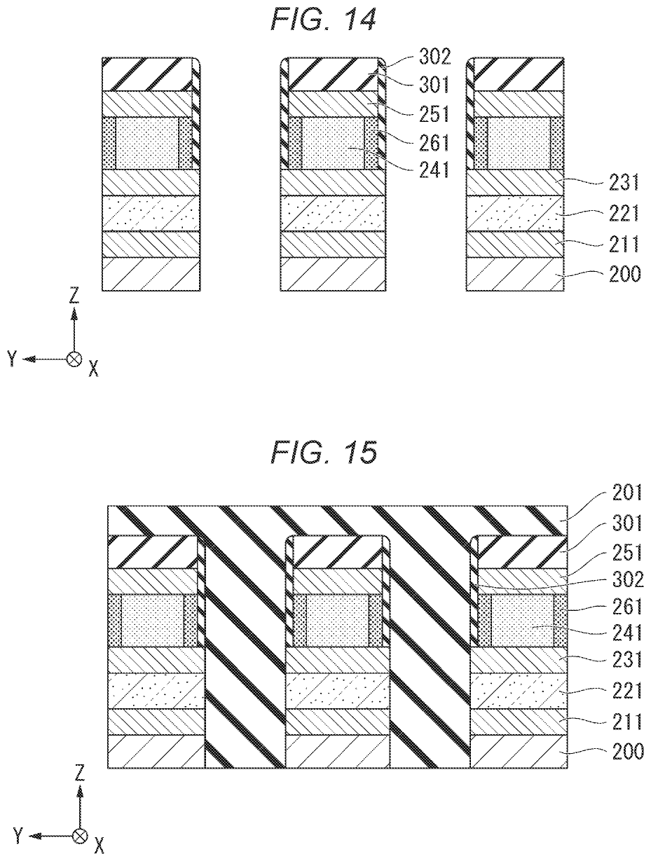

Next, as shown in FIG. 14, the stacked structure body of the conductive layer 231, the semiconductor layer 221, the conductive layer 211, and the conductive layer 200 is divided in the Y direction by anisotropic etching, such as RIE, using the hard mask 301.

Then, as shown in FIG. 15, an insulating layer 201 is formed between the stacked bodies that are divided by etching, and the upper surface of the insulating layer 201 and the hard mask 301 are ground by chemical mechanical polishing (CMP) or other method, to expose the upper surface of the conductive layer 251.

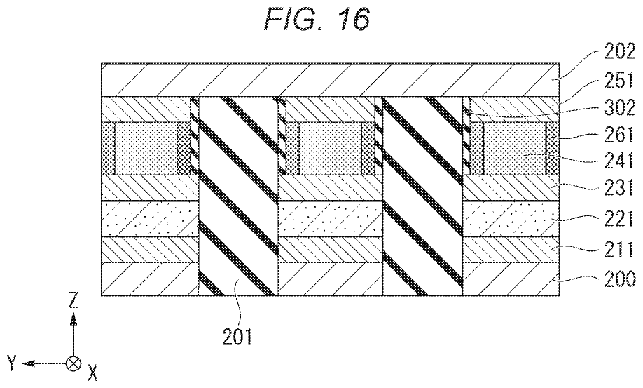

Thereafter, as shown in FIG. 16, a conductive layer 202 for the bit line BL is formed above the exposed conductive layer 251.

The similar manufacturing process is repeated in the X direction, whereby a semiconductor storage device having approximately the same structure as the memory cell MC13 shown in FIG. 16 is produced.

Instead of forming the protective layer 261 by a method such as ion implantation, plasma doping, or annealing treatment after gas implantation, the protective layer 261 may be formed on the side surface of the phase change film PCM, as a side wall film. The side wall film is formed by, for example, ALD or CVD, and contains at least one kind of element selected from the group consisting of chalcogen, such as Te, Ge, and Sb, and at least one kind of element selected from the group consisting of N, C, B, and O. The protective layer 261 may be formed by solid phase diffusion after the side wall film is formed. Employing these methods enables manufacturing the semiconductor storage device having the memory cell that includes the protective film 27A, 27B, 27C, 27E, or 27F as shown in FIGS. 4 to 6, 8, and 9, respectively.

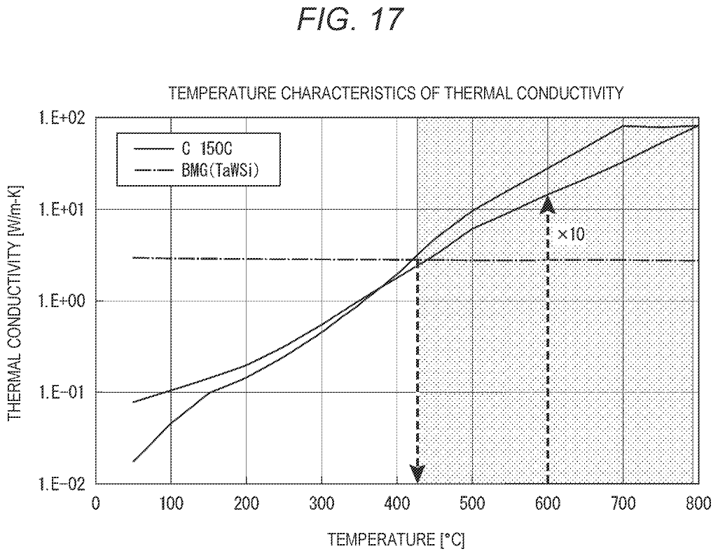

FIG. 17 is a graph showing result of measuring temperature dependence of thermal conductivity with respect to a carbon film and an amorphous alloy film.

The measurement result that is indicated as “C 150C” in FIG. 17 shows a temperature dependence of thermal conductivity of a carbon film that was deposited on a substrate at 150° C. On the other hand, the measurement result that is indicated as “BMG” shows a temperature dependence of thermal conductivity of an amorphous alloy film having a composition of Ta₁W₁Si₁.

As shown in FIG. 17, the amorphous alloy film exhibits approximately the same thermal conductivity from a normal temperature to 800° C. On the other hand, the carbon film has a thermal conductivity lower than that of the amorphous alloy film in a temperature region of 400° C. or lower. However, the thermal conductivity increases by temperature rise, and, in a high-temperature region of higher than 400° C. and 800° C. or less, the thermal conductivity gradually increases as the temperature rises, to be higher than the thermal conductivity of the amorphous alloy film.

This reveals that the carbon film conducts heat more than the amorphous alloy film in the high-temperature region of from 400 to 800° C., but tends to conduct heat less than the amorphous alloy film in the low-temperature region of 400° C. or lower.

As compared with a case of forming the lower electrode layer 20, the intermediate electrode layer 22, and the upper electrode layer 26 by using carbon-based carbon electrode layers, electrode layers that are formed of amorphous alloy are advantageous as electrodes that constitute the memory cell. This reason is described below.

The phase change film PCM starts to melt at around 600° C. and becomes an amorphous state (reset state) when being heated to the melting temperature or higher and then being rapidly cooled from the heating temperature. The phase change film PCM becomes a crystalline state (set state) when being heated at a temperature lower than the melting temperature but higher than the crystallization temperature and then being cooled. Thus, the phase change film PCM repeats melting and solidification by resetting and setting. From this point of view, in rapidly cooling to the low-temperature region, the carbon film electrode layer exhibits low thermal conductivity, causing low cooling efficiency. In contrast, the amorphous alloy electrode layer exhibits high thermal conductivity in the low-temperature region and provides high cooling efficiency, which is advantageous in rapidly cooling the phase change film PCM to reset it. On the other hand, the amorphous alloy film is superior in a heat retaining property to the carbon film in the high-temperature region of higher than 600° C. From these reasons, a structure using the amorphous alloy electrode layer contributes to reduction of a reset current I_{RESET} more than a structure using the carbon-based electrode layer.

As shown in FIG. 17, in comparison with the thermal conductivity of the carbon film at 600° C., which is the melting point of Ta₄₀W₄₀Si₂₀, the thermal conductivity of the amorphous alloy film is approximately one-tenth of that of the carbon film. This reveals that changing the carbon film electrode layer to the amorphous alloy film electrode layer enables reducing the film thickness while the heat retaining property is maintained to a degree similar to that of the carbon film.

Thus, as compared with a structure using the carbon film electrode layer, use of the amorphous alloy film electrode layer makes it possible to provide a stacked structure that has a reduced aspect ratio and thereby contributes to integration as a memory cell.

In the case of using the carbon film electrode layer in a memory cell, element diffusion tends to occur between the phase change film PCM and the carbon film. Thus, it is necessary to arrange a barrier layer at an interface between the carbon film electrode layer and the phase change film PCM, in the case of using the carbon film electrode layer.

In this point, use of the electrode layer that is made of the above-described amorphous alloy enables omitting the barrier layer. In the present disclosure, the barrier layer is omitted in the structures shown in FIGS. 4, 6, 7, and 9, and therefore, the manufacturing process can be simplified accordingly. For example, the structure shown in FIG. 4 enables the manufacturing process to be simpler than that for the structure provided with the barrier layer shown in FIG. 5, and the structure shown in FIG. 9 enables the manufacturing process to be simpler than that for the structure that is provided with the barrier layer shown in FIG. 8.

In the case of omitting the barrier layer, the layer structure is simpler than the layer structure provided with the barrier layer, whereby the film deposition process can be simplified in manufacturing a memory cell.

In addition, use of the carbon film electrode layer is prone to generate dust in the film deposition process. In this point, the above-described amorphous alloy is unlikely to generate dust in the film deposition process.

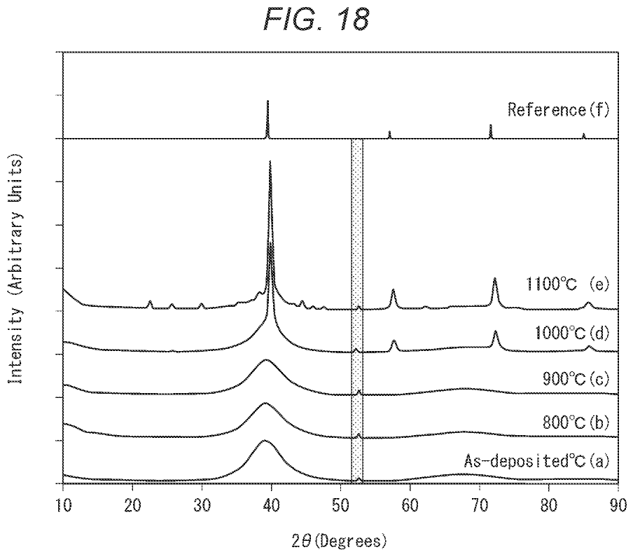

FIG. 18 is a graph showing result of X-ray diffraction analysis of an amorphous alloy having a composition of Ta₁W₁Si₁ in an as-deposited state and at 800, 900, 1000, and 1100° C. The amorphous alloy remains having the amorphous structure until the temperature is 900° C. Assuming that the phase change film PCM provided in the memory cell starts to melt at around 600° C., this is a temperature range in which the amorphous alloy electrode layer can be used in the amorphous state without occurring any problem. Thus, the above-described amorphous alloy is effective as a material for forming an electrode layer of a memory cell.

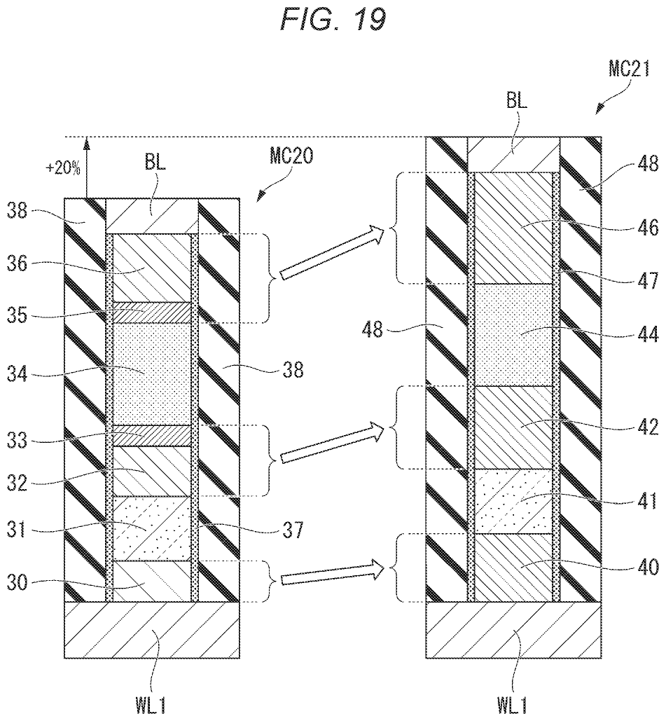

FIG. 19 is an explanatory diagram showing comparison between memory cells: one has a structure in which carbon film electrode layers are used and barrier layers are provided, and the other has a structure in which amorphous alloy films are used but a barrier layer is omitted.

The memory cell MC20 shown on the left side in FIG. 19 includes a lower electrode layer 30, a selector 31, an intermediate electrode layer 32, a barrier layer 33, a phase change film (storage layer) 34, a barrier layer 35, and an upper electrode layer 36, which are stacked, in this order, in the Z direction from the word line WL1 to the bit line BL.

In addition, side surfaces of the lower electrode layer 30, the selector 31, the intermediate electrode layer 32, the barrier layer 33, the phase change film 34, the barrier layer 35, and the upper electrode layer 36, are covered with protective layers 37, and insulating layers 38 are provided outside of the protective layers 37.

The lower electrode layer 30 can be formed of CN, the intermediate electrode layer 32 can be formed of a carbon film, and the barrier layer 33 can be formed of WN. The phase change film 34 can be formed of an alloy containing germanium, antimony, and tellurium, the barrier layer 35 can be formed of WN, and the upper electrode layer 36 can be formed of a carbon film.

In consideration of a practical semiconductor storage element, the memory cell MC20 can be set as follows. For example, the film thickness of the lower electrode layer 30 is 10 nm, the film thickness of the selector 31 is 15 nm, the film thickness of the intermediate electrode layer 32 is 15 nm, the film thickness of the barrier layer 33 is 3 nm, the film thickness of the phase change film 34 is 37 nm, the film thickness of the barrier layer 35 is 3 nm, and the film thickness of the upper electrode layer 36 is 18 nm. In the memory cell MC20, the total thickness of the films interposed between the word line WL1 and the bit line BL is 101 nm.

On the other hand, the memory cell MC21 shown on the right side in FIG. 19 has a structure equivalent to that of the first embodiment shown in FIG. 4 and includes a lower electrode layer 40, a selector 41, an intermediate electrode layer 42, a phase change film 44, and an upper electrode layer 46, which are stacked, in this order, in the Z direction from the word line WL1 to the bit line BL.

The lower electrode layer 40 can be formed of the above-described amorphous alloy, and the intermediate electrode layer 42 can be formed of the above-described amorphous alloy. The phase change film 44 can be formed of an alloy containing germanium, antimony, and tellurium, and the upper electrode layer 46 can be formed of the above-described amorphous alloy.

In addition, side surfaces of the lower electrode layer 40, the selector 41, the intermediate electrode layer 42, the phase change film 44, and the upper electrode layer 46, are covered with protective layers 47, and insulating layers 48 are provided outside of the protective layers 47.

In consideration of a practical semiconductor storage element, the memory cell MC21 can be set as follows. For example, the film thickness of the lower electrode layer 40 is 16 nm, the film thickness of the selector 41 is 15 nm, the film thickness of the intermediate electrode layer 42 is 24 nm, the film thickness of the phase change film 44 is 37 nm, and the film thickness of the upper electrode layer 46 is 29 nm.

In the memory cell MC21, the total thickness of the films interposed between the word line WL1 and the bit line BL is 121 nm.

When the electrode layer is made of the TaWSi system amorphous alloy, the thermal conductivity is 2.39 W/mK, and the resistivity is 2×e⁻⁴ Ω/cm. On the other hand, a carbon film having a film thickness of 20 nm exhibits thermal conductance of 7.25e⁷ W/K and resistance of 1×e⁻⁷Ω or lower. The resistivity is reduced by two or more digits as compared to the resistivity of the carbon film.

When the amorphous alloy electrode layer is set to have a film thickness of 33 nm assuming that it has a thermal conductivity approximately equal to that of the carbon film electrode layer, thermal conductance is 7.24e⁷ W/K, and resistance is 7e⁻¹⁰Ω. In view of this, as shown by comparison in FIG. 19, in the case of changing the memory cell MC20 using the carbon film electrode layers, to the memory cell MC21 using the amorphous alloy electrode layers, although the whole height of the cell is increased by approximately 20%, the resistance value is reduced by 2 or more digits.

Thus, as compared with the semiconductor storage device using the carbon film as the electrode layer, the semiconductor storage device including the amorphous alloy electrode layer can be greatly reduced in threshold voltage V_{TH}.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor storage device, comprising:
at least a first electrode layer including a first material; and
a memory layer including a second material having a high-resistance state and a low-resistance state switchable based on electric heating,
wherein the memory layer has a side surface covered by a side wall layer, the side wall layer including a third material with a higher melting temperature than the second material,
wherein the first material has an amorphous structure, a thermal conductivity at least 2-digits lower than a thermal conductivity of a single phase metal, and a resistivity equal to or lower than 50 mΩ·cm and a positive temperature dependence.

2. The semiconductor storage device according to claim 1, wherein the first material includes two or more refractory metals M1 from the following: W, Mo, Ta, Nb, Rh, and Ni.

3. The semiconductor storage device according to claim 1, wherein the first material contains two or more refractory metals M1, and contains one or more semimetal or nonmetal elements M2 from the following: B, C, N, Al, Si, P, S, Ge, As, and Se.

4. The semiconductor storage device according to claim 1, wherein the first material contains Fe, and contains one or more elements M3 from the following: Tb, Gd, Co, B, Ni, Cr, and P.

5. The semiconductor storage device according to claim 1, wherein the first material contains Zr, Cu, and one or more elements M4 from the following: Al, Ni, Ti, Nb, and Be.

6. The semiconductor storage device according to claim 1, wherein the first material contains Pd, Ni, and one or both of P or Cu.

7. The semiconductor storage device according to claim 1, further comprising a second electrode layer, wherein the memory layer is interposed between the first and second electrode layers.

8. The semiconductor storage device according to claim 1, further comprising:
a second electrode layer;
a first barrier layer; and
a second barrier layer, wherein the first barrier layer is interposed between the memory layer and the first electrode layer, and the second barrier layer is interposed between the memory layer and the second electrode layer.

9. The semiconductor storage device according to claim 1, further comprising:
a second electrode layer, wherein the memory layer is interposed between the first and second electrode layers; and
a selector layer.

10. The semiconductor storage device according to claim 1, further comprising:
a second electrode layer;
a first barrier layer interposed between the memory layer and the first electrode layer;
a second barrier layer interposed between the memory layer and the second electrode layer; and
a selector layer.

11. The semiconductor storage device according to claim 1, further comprising:
a second electrode layer including the first material, wherein the memory layer is interposed between the first and second electrode layers;
a third electrode layer; and
a selector layer.

12. The semiconductor storage device according to claim 1, further comprising:
a second electrode layer;
a first barrier layer interposed between the memory layer and the first electrode layer;
a second barrier layer interposed between the memory layer and the second electrode layer;
a third electrode layer; and
a selector layer.

13. The semiconductor storage device according to claim 1, further comprising:
a second electrode layer, wherein the memory layer is interposed between the first c electrode layer and the second electrode layer; and
a side wall layer provided along a side surface of the memory layer, the side wall layer containing the second material and at least one of: nitrogen, carbon, boron, or oxygen.

14. A method, comprising:
forming a memory layer over a first conductor layer, wherein the memory layer includes a first material having a high-resistance state and a low-resistance state switchable based on electric heating;
forming a second conductor layer over the memory layer, wherein at least one of the first or second conductor layer includes a second material;
patterning the memory layer and the second conductor layer;
forming a side wall layer extending along a side surface of the memory layer, wherein the side wall layer includes a third material with a higher melting temperature than the first material,
wherein the second material has an amorphous structure, a thermal conductivity at least 2-digits lower than a thermal conductivity of a single phase metal, and a resistivity equal to or lower than 50 mΩ·cm and a positive temperature dependence.

15. The method of claim 14, further comprising patterning the first conductor layer to form a stacked structure.

16. The method of claim 14, wherein the step of forming a side wall layer includes incorporating at least one of: N, C, B, or O into the side surface of the memory layer through at least one of: ion implantation, plasma doping, or annealing treatment after gas implantation.

17. The method of claim 14, wherein the second material includes two or more refractory metals M1 from the following: W, Mo, Ta, Nb, Rh, and Ni.

18. The method of claim 14, wherein the second material contains Fe and one or more elements M3 from the following: Tb, Gd, Co, B, Ni, Cr, and P.

19. The method of claim 14, wherein the second material contains Zr, Cu, and one or more elements M4 from the following: Al, Ni, Ti, Nb, and Be.

20. The method of claim 14, wherein the second material contains Pd, Ni, and either or both of P and Cu.
